(19) United States
(12) Patent Application Publication
(10) Pub. No.: US 2025/0266928 A1
(43) Pub. Date: Aug. 21, 2025

(54) METHOD FOR DETERMINING AUXILIARY BIT OF POLAR CODE AND APPARATUS

(71) Applicant: HUAWEI TECHNOLOGIES CO., LTD., Shenzhen (CN)

(72) Inventors: Jiajie TONG, Hangzhou (CN); Xianbin WANG, Hangzhou (CN); Huazi ZHANG, Hangzhou (CN); Shengchen DAI, Hangzhou (CN); Rong LI, Boulogne Billancourt (FR); Jun WANG, Hangzhou (CN)

(21) Appl. No.: 19/068,297

(22) Filed: Mar. 3, 2025

Related U.S. Application Data
(63) Continuation of application No. 18/328,137, filed on Jun. 2, 2023, now Pat. No. 12,273,197.
Application No. 18/328,137 is a continuation of application No. PCT/CN2021/135211, filed on Dec. 3, 2021.

(30) Foreign Application Priority Data
Dec. 3, 2020 (CN) 202011394710.9

(51) Int. Cl. H04L 1/00; H03M 13/00; H03M 13/09

(52) U.S. Cl. CPC H04L 1/0057; H03M 13/09; H03M 13/611; H04L 1/0042

(57) ABSTRACT

This application provides a method for determining an auxiliary bit of a polar code and an apparatus. The method includes: determining at least K sub-channels based on reliability of a first sub-channel set, where the K sub-channels carry information bits, S sub-channel subsets are determined based on the first sub-channel set, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, and the auxiliary bits may be known redundancy check RC bits; and then performing polar encoding on the information bits and the auxiliary bits, to output polar-encoded data.

### CROSS-REFERENCE TO RELATED APPLICATIONS

This application a continuation of U.S. patent application Ser. No. 18/328,137, filed on Jun. 2, 2023, which is a continuation of International Application No. PCT/CN2021/135211, filed on Dec. 3, 2021, which claims priority to Chinese Patent Application No. 202011394710.9, filed on Dec. 3, 2020. All of the afore-mentioned patent applications are hereby incorporated by reference in their entireties.

### TECHNICAL FIELD

This application generally relates to a data communication method and apparatus, and specifically, to a method for determining an auxiliary bit of a polar code and an apparatus.

### BACKGROUND

A polar code (polar code) is a linear block error correction code for improving an overall transmission capacity through channel polarization. Specifically, the polar code is designed such that information bits are transmitted on more-reliable sub-channels (for example, sub-channels with less noise), and fixed (frozen) bits are transmitted on less-reliable sub-channels (for example, sub-channels with more noise). In a conventional technology, a cyclic redundancy check CRC bit and the like are used to assist in decoding. Determination of factors, such as a quantity, types, and locations, of auxiliary bits is a key to polar code construction, and may affect polar code performance.

### SUMMARY

Embodiments of this application disclose a method for determining an auxiliary bit of a polar code and an apparatus. Under a specific condition, this communication method achieves performance equivalent to that of a conventionally constructed polar code, and compared with a decoder for a conventionally constructed polar code, can reduce an area of a decoder chip and lower complexity of decoding implementation.

According to a first aspect, this application provides a communication method for polar code encoding. The method includes: determining at least K sub-channels based on reliability of a first sub-channel set, where the K sub-channels carry information bits, S sub-channel subsets are determined based on the first sub-channel set, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers; and performing polar encoding on the information bits and the auxiliary bits, and outputting polar-encoded data. The method further includes obtaining the information bits. Optionally, the information bits may be obtained before the at least K sub-channels are determined based on the reliability of the first sub-channel set.

Use of the communication method provided in this application can effectively reduce overheads caused by calculation of the auxiliary bits such as a CRC, lower implementation complexity, and reduce area overheads of a decoder. In addition, simulation verification shows that the method has good performance under specific conditions such as a specific code length and a specific code rate, and can maintain FER performance and FAR performance that are not apparently different from a conventional polar code encoding/decoding method.

Correspondingly, according to a second aspect, this application further provides a communication method for polar code decoding. The method includes: receiving an encoded sequence, where the encoded sequence is obtained by performing polar encoding on a first bit sequence, a first sub-channel set corresponding to the first bit sequence includes at least K sub-channels determined based on reliability of the first sub-channel set, the K sub-channels carry information bits, the first sub-channel set includes S sub-channel subsets, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers; and performing polar decoding based on the encoded sequence, to obtain the information bits.

In a possible implementation, the first sub-channel set is a channel set from which a shorten sub-channel is excluded. Rate matching is a common means for implementing any code length. Sub-channels that are subject to impact of rate matching are considered for the first sub-channel set, which is a more specific implementation solution. The impact of rate matching may refer to impact of an operation such as puncturing, shortening, or repetition. More specifically, for the impact of rate matching, sub-channels that are frozen in consideration of rate matching may also be included.

In a possible implementation, the determining at least K sub-channels based on reliability of a first sub-channel set includes: determining (K+J) sub-channels based on the reliability of the first sub-channel set, where the J sub-channels carry auxiliary bits. In this implementation, the (K+J) sub-channels are selected based on reliability. Such a design makes the solution clear, and from an implementation perspective, does not increase complexity of solution implementation.

In a possible implementation, the Ki sub-channels carry information bits. To be specific, all the Ki sub-channels allocated in the i^{th} segment carry the information bits.

In a possible implementation, (Ki+Ji) sub-channels are determined based on reliability of the i^{th} sub-channel subset, where the (Ki+Ji) sub-channels carry information bits and the auxiliary bits. After the K sub-channels are determined, the (Ki+Ji) sub-channels that carry the information bits and the auxiliary bits in each segment need to be considered based on the K sub-channels, to prepare for further determining locations for the information bits and the auxiliary bits subsequently. In a possible implementation, reliability of the (Ki+Ji) sub-channels is higher than reliability of a remaining sub-channel in the i^{th} sub-channel subset.

In a possible implementation, the determining at least K sub-channels based on reliability of a first sub-channel set includes determining K sub-channels based on the reliability of the first sub-channel set. In this implementation, the K sub-channels are selected based on reliability. Compared with selecting (K+J) sub-channels, the step of determining at least K sub-channels are simpler.

In a possible implementation, sequence numbers of the Ji sub-channels are greater than a sequence number of a remaining sub-channel in the i^{th} sub-channel subset. In other words, placement locations (sequence numbers) of the auxiliary bits need to be last locations of physical addresses or natural sequence numbers in optional locations in the i^{th} segment, and the locations of the auxiliary bits are after the information bits and the frozen bits (if any).

In a possible implementation, the Ki sub-channels are determined based on reliability of a third sub-channel set, where the third sub-channel set is the i^{th} sub-channel subset from which the Ji sub-channels are excluded, and the Ki sub-channels carry the information bits. Following the foregoing implementation, in this implementation, after Ji sub-channels for placing the auxiliary bits are determined, locations for placing the information bits are selected from a set of remaining sub-channels. More specifically, the locations may be selected based on reliability. In a possible implementation, reliability of the Ki sub-channels is higher than reliability of a remaining sub-channel in the third sub-channel set.

In a possible implementation, the first sub-channel set is segmented, where the first sub-channel set includes the S sub-channel subsets.

In a possible implementation, the K sub-channels further carry a pre-frozen bit.

In a possible implementation, a total quantity J of the auxiliary bits is determined based on a quantity T of times of checking a check result of the auxiliary bits during polar decoding, and T is a positive integer. In a specific case or some cases, the total quantity J of the auxiliary bits is greater than or equal to log₂(T). Alternatively, the total quantity J of the auxiliary bits is greater than or equal to log₂(T*CN), and CN is a quantity of candidate locations that need to be blindly detected. Alternatively, the total quantity J of the auxiliary bits is greater than or equal to Σ_{i∈s}(log(Tᵢ)+Cᵢ), and Cᵢ is an integer. Alternatively, the total quantity J of the auxiliary bits is a nonnegative integer power of 2. More specifically, in a possible implementation, in a communication system without blind detection, the total quantity J of the auxiliary bits is greater than or equal to log₂(T). Alternatively, in a communication system with blind detection, the total quantity J of the auxiliary bits is greater than or equal to log₂(T*CN). CN is a quantity of candidate locations that need to be blindly detected. Alternatively, in an asymmetric block-combined ABC polar code communication system, the total quantity J of the auxiliary bits is greater than or equal to Σ_{i∈s}(log(Tᵢ)+Cᵢ), and Cᵢ is an integer. In another possible implementation, in a communication system with low power consumption, the total quantity J of the auxiliary bits is a nonnegative integer power of 2. The foregoing methods for determining quantities in different scenarios may be used with reference to each other, or are interchangeable. For example, in a communication system without blind detection, the total quantity J of the auxiliary bits may be greater than or equal to log₂(T*CN), or the total quantity J may be greater than or equal to Σ_{i∈s}(log(Tᵢ)+Cᵢ). From a perspective of simplified engineering implementation, a method for determining a quantity J of auxiliary bits may be used for compatibility with a plurality of different scenarios. For example, the total quantity J is a nonnegative integer power of 2.

In a possible implementation, a value of the auxiliary bit is 0 or 1. Alternatively, a value of the auxiliary bit is determined based on a part or all of a terminal identifier UE-ID, or a value of the auxiliary bit is determined based on a part or all of a base station identifier BS-ID. Alternatively, a value of the auxiliary bit is determined based on a part or all of the terminal identifier UE-ID and a part or all of the base station identifier BS-ID.

According to a third aspect, this application provides a communication apparatus. The apparatus includes a logic circuit, configured to determine at least K sub-channels based on reliability of a first sub-channel set, where the K sub-channels carry information bits, S sub-channel subsets are determined based on the first sub-channel set, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers; and perform polar encoding on the information bits and the auxiliary bits; and a communication interface, configured to output polar-encoded data. Use of the apparatus provided in this application can effectively reduce overheads caused by calculation of the auxiliary bits such as a CRC, lower implementation complexity, and reduce area overheads of a decoder. In addition, simulation verification shows that the apparatus has good performance under specific conditions such as a specific code length and a specific code rate, and can maintain FER performance and FAR performance that are not apparently different from a conventional polar code encoding/decoding apparatus.

Correspondingly, according to a fourth aspect, this application further provides a communication apparatus for decoding. The apparatus includes an obtaining module, configured to obtain an encoded sequence, where the encoded sequence is obtained by performing polar encoding on a first bit sequence, a first sub-channel set corresponding to the first bit sequence includes at least K sub-channels determined based on reliability of the first sub-channel set, the K sub-channels carry information bits, the first sub-channel set includes S sub-channel subsets, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers; and a decoding module, configured to perform polar decoding based on the encoded sequence, to obtain the information bits.

In a possible implementation, the first sub-channel set is a channel set from which a shorten sub-channel is excluded. Rate matching is a common means for implementing any code length. Sub-channels that are subject to impact of rate matching are considered for the first sub-channel set, which is a more specific implementation solution. The impact of rate matching may refer to impact of an operation such as puncturing, shortening, or repetition. More specifically, for the impact of rate matching, sub-channels that are frozen in consideration of rate matching may also be included.

In a possible implementation, that the at least K sub-channels are determined based on the reliability of the first sub-channel set includes: determining (K+J) sub-channels based on the reliability of the first sub-channel set, where the J sub-channels carry auxiliary bits. In this implementation, the (K+J) sub-channels are selected based on reliability. Such a design makes the solution clear, and from an implementation perspective, does not increase complexity of solution implementation.

In a possible implementation, the Ki sub-channels carry information bits. To be specific, all the Ki sub-channels allocated in the i^{th} segment carry the information bits.

In a possible implementation, (Ki+Ji) sub-channels are determined based on reliability of the i^{th} sub-channel subset, where the (Ki+Ji) sub-channels carry information bits and the auxiliary bits. After the K sub-channels are determined, the (Ki+Ji) sub-channels that carry the information bits and the auxiliary bits in each segment need to be considered based on the K sub-channels, to prepare for further determining locations for the information bits and the auxiliary bits subsequently. In a possible implementation, reliability of the (Ki+Ji) sub-channels is higher than reliability of a remaining sub-channel in the i^{th} sub-channel subset.

In a possible implementation, the determining at least K sub-channels based on reliability of a first sub-channel set includes determining K sub-channels based on the reliability of the first sub-channel set. In this implementation, the K sub-channels are selected based on reliability. Compared with selecting (K+J) sub-channels, the step of determining at least K sub-channels are simpler.

In a possible implementation, sequence numbers of the Ji sub-channels are greater than a sequence number of a remaining sub-channel in the i^{th} sub-channel subset. In other words, placement locations (sequence numbers) of the auxiliary bits need to be last locations of physical addresses or natural sequence numbers in optional locations in the i^{th} segment, and the locations of the auxiliary bits are after the information bits and the frozen bits (if any).

In a possible implementation, the logic circuit is further configured to determine the Ki sub-channels based on reliability of a third sub-channel set, where the third sub-channel set is the i^{th} sub-channel subset from which the Ji sub-channels are excluded, and the Ki sub-channels carry the information bits. Following the foregoing implementation, in this implementation, after Ji sub-channels for placing the auxiliary bits are determined, locations for placing the information bits are selected from a set of remaining sub-channels. More specifically, the locations may be selected based on reliability. In a possible implementation, reliability of the Ki sub-channels is higher than reliability of a remaining sub-channel in the third sub-channel set.

In a possible implementation, the logic circuit is further configured to segment the first sub-channel set, where the first sub-channel set includes the S sub-channel subsets.

In a possible implementation, the K sub-channels further carry a pre-frozen bit.

In a possible implementation, a total quantity J of the auxiliary bits is determined based on a quantity T of times of checking a check result of the auxiliary bits during polar decoding, and T is a positive integer. In a possible implementation, in a communication system without blind detection, the total quantity J of the auxiliary bits is greater than or equal to log₂(T). Alternatively, in a communication system with blind detection, the total quantity J of the auxiliary bits is greater than or equal to log₂(T*CN). CN is a quantity of candidate locations that need to be blindly detected. Alternatively, in an asymmetric block-combined ABC polar code communication system, the total quantity J of the auxiliary bits is greater than or equal to Σ_{i∈s}(log(Tᵢ)+Cᵢ), and Cᵢ is an integer. In another possible implementation, in a communication system with low power consumption, the total quantity J of the auxiliary bits is a nonnegative integer power of 2.

In a possible implementation, a value of the auxiliary bit is 0 or 1. Alternatively, a value of the auxiliary bit is determined based on a part or all of a terminal identifier UE-ID, or a value of the auxiliary bit is determined based on a part or all of a base station identifier BS-ID. Alternatively, a value of the auxiliary bit is determined based on a part or all of the terminal identifier UE-ID and a part or all of the base station identifier BS-ID.

According to a fifth aspect, this application provides a communication apparatus, including a processor and a memory. The memory stores at least one group of programs, and the programs may be executed by the processor, to enable the communication apparatus to be configured to perform the method according to the first aspect and the possible implementations of the first aspect, or perform the method according to the second aspect and the possible implementations of the second aspect.

According to a sixth aspect, this application provides a computer-readable storage medium. The computer-readable storage medium is configured to store instructions. When the instructions are executed, the method according to the first aspect and the possible implementations of the first aspect is implemented, or the method according to the second aspect and the possible implementations of the second aspect is implemented.

According to a seventh aspect, this application provides a computer program product, including a computer program. When being executed by a processor, the computer program implements the method according to the first aspect and the possible implementations of the first aspect, or implements the method according to the second aspect and the possible implementations of the second aspect.

For technical effects brought by the fifth aspect to the seventh aspect, refer to technical effects brought by the first aspect and any possible design of the first aspect, or refer to technical effects brought by the second aspect and any possible design of the second aspect. Details are not described again.

According to an eighth aspect, a communication system is provided. The communication system includes the communication apparatus for encoding and the communication apparatus for decoding according to any one of the third aspect and the fourth aspect, or the communication apparatus for encoding and the communication apparatus for decoding according to the fifth aspect.

### BRIEF DESCRIPTION OF DRAWINGS

To clearly understand technical solutions and advantages of this application, the following descriptions may be read with reference to the accompanying drawings.

FIG. 1 is a schematic diagram depicting how a polar encoding generator matrix can be generated from a core;

FIG. 2 is a schematic diagram of example usage of and an example polar encoder of a polar encoding generator matrix for generating a codeword;

FIG. 3 is a schematic diagram of a partial example decision tree whose width is limited by a maximum given list size L and that is used in a successive cancellation list (Successive Cancellation List, SCL) polar decoder;

FIG. 4 is a schematic diagram of an architecture of a communication system according to this application;

FIG. 5 is a schematic flowchart of a communication method for polar encoding according to this application;

FIG. 6 is a schematic diagram of an encoding procedure of polar encoding in a possible specific embodiment according to this application;

FIG. 7A and FIG. 7B are a simulation diagram of FER performance of three polar codes under conditions such as different quantities K of information bits and a same code length N;

FIG. 8 is a schematic diagram of an auxiliary-bit calculation circuit commonly used in an existing LIST decoder;

FIG. 9 is a schematic diagram of a communication apparatus 900 for polar encoding according to this application;

FIG. 10 is a schematic flowchart of a communication method for polar decoding according to this application;

FIG. 11 is a schematic diagram of a communication apparatus 1100 for polar encoding according to this application;

FIG. 12 is a schematic diagram of a polar code communication apparatus 1200 according to this application; and

FIG. 13 is a schematic diagram of a polar code communication apparatus 1300 according to this application.

### DESCRIPTION OF EMBODIMENTS

The following describes embodiments of this application in detail with reference to the accompanying drawings. However, it should be understood that a specific concept provided in this application may be implemented in a plurality of specific environments. The specific embodiments are merely used to describe and explain specific manners of this application, and should not be understood as limiting the scope of this application.

In the specification, claims, and accompanying drawings of this application, the terms “first”, “second”, “third”, “fourth”, and the like are intended to distinguish between different objects but do not indicate a particular order. In addition, the terms “including”, “having”, or any other variant thereof are intended to cover a non-exclusive inclusion. For example, a process, a method, a system, a product, or a device that includes a series of steps or units is not limited to the listed steps or units, but optionally further includes unlisted steps or units, or optionally further includes other inherent steps or units of the process, the method, the product, or the device.

An “embodiment” mentioned in this specification means that a particular feature, structure, or characteristic described with reference to this embodiment may be included in at least one embodiment of this application. The phrase appear at various locations in this specification may neither necessarily mean a same embodiment, nor mean an independent or optional embodiment exclusive from another embodiment. It is explicitly and implicitly understood by a person skilled in the art that embodiments described in the specification may be combined with another embodiment.

In this application, “at least one (item)” means one or more, “a plurality of” means two or more, “at least two (items)” means two, three, or more, and “and/or” is used to describe an association relationship between associated objects and indicates that three relationships may exist. For example, “A and/or B” may indicate the following three cases: Only A exists, only B exists, and both A and B exist, where A and B may be singular or plural. The character “/” generally indicates an “or” relationship between associated objects. “At least one of the following items (pieces)” or a similar expression thereof refers to any combination of these items, including any combination of singular items (pieces) or plural items (pieces). For example, at least one of a, b, or c may indicate a, b, c, “a and b”, “a and c”, “b and c”, or “a, b, and c”, where a, b, and c may be singular or plural.

The terms “sub-channel” and “channel” in the claims and specification of this application and related terms, such as “sub-channel set” and “channel set”, are generally not distinguished in meaning, and only comply with a language habit of a person skilled in the art, to facilitate understanding of a person skilled in the art. The foregoing terms are not distinguished in a strict sense during use, and may be used interchangeably. Without loss of generality, this application uses “sub-channel” as an example for description.

To help understand the subsequent embodiments in more detail and other inventive aspects of the embodiments, the following briefly describes a polar code.

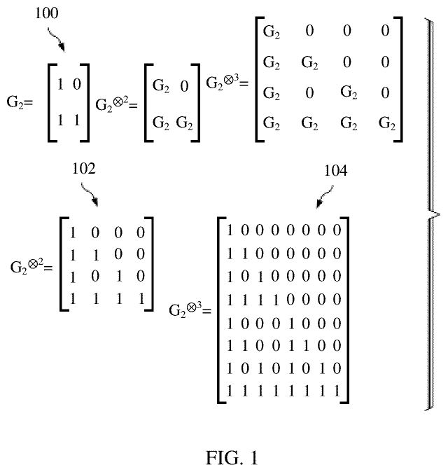

An encoding policy of a polar code, or referred to as a Polar code (Polar Codes), is to transmit, through a noise-free channel, information that is useful to a user, and to transmit agreed information or not to transmit information on a noisy channel, so as to improve reliability of data transmission and ensure communication quality. The polar code is also a linear block code, and has low encoding and decoding complexity. An encoding matrix of the polar code is G_{N}, and an encoding process may be expressed as x₁^{N}=u₁^{N}G_{N}, where u₁^{N}=(u₁, u₂, . . . u_{N}) is a binary row vector, and a length is N (that is, a code length). G_{N} is an N×N matrix generated from a core. FIG. 1 is a diagram illustrating, through an illustrative example, how a polar encoding generator matrix can be generated from a core G₂ 100. It should be noted that FIG. 1 is merely an example. There may be a core in another form, for example, a prime number core (for example, 3×3 or 5×5) or a combination of (prime number or non-prime number) cores for generating a higher-order core. Polarization comes from a “nesting” mode, and a generator matrix is created from a core (or a combination of cores) in a “nesting” mode. In FIG. 1, a 2-order Kronecker product matrix G₂^{⊗}^{²} and a 3-order Kronecker product matrix G₂^{⊗}^{³} 104 are examples of the polar encoding generator matrix. The method for generating a matrix shown in FIG. 1 may be extended to produce an m-order Kronecker product matrix G₂^{⊗m}. For example, G_{N}=G₂^{⊗}^{^{(log2(N))}}, and G₂^{⊗}^{^{(log2(N))}} is defined as a Kronecker (Kronecker) product of log₂ N matrices G2.

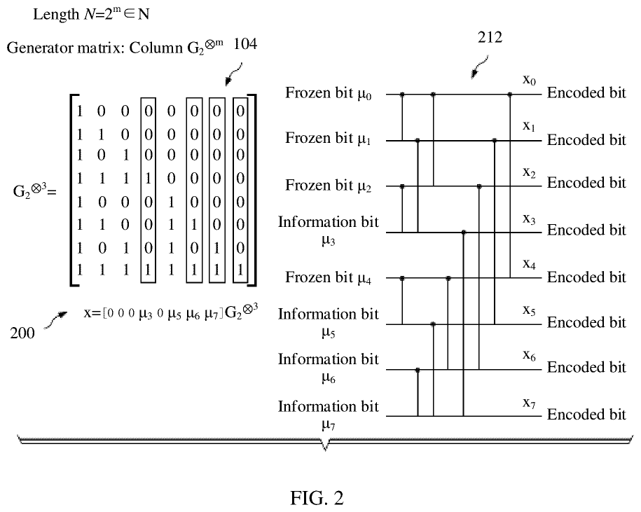

A polar code may be formed based on a Kronecker product matrix of the matrix core G₂ 100. For a polar code whose codeword length satisfies N=2^{m}, the generator matrix is G₂^{⊗m} FIG. 2 is a schematic diagram illustrating example usage of and an example polar encoder of a polar encoding generator matrix for generating a codeword. In FIG. 2, a generator matrix G₂^{⊗}^{³} 104 is used to generate a codeword whose length is 2³=8. A codeword x is formed based on a product of an input vector u=[0 0 0 u₃ 0 u₅ u₆ u₇] and the generator matrix G₂^{⊗}^{³} 104, as shown by 200. The input vector u includes information bits and fixed or frozen bits. In a specific example shown in FIG. 2, because N=8, the input vector u is an 8-bit vector, and the codeword x is an 8-bit vector. The input vector has frozen bits at locations 0, 1, 2, and 4, and information bits at locations 3, 5, 6, and 7. 212 represents an example implementation of an encoder that generates a codeword, where the frozen bits are all set to 0, and a bold “.” symbol represents modulo-2 addition. For the example in FIG. 2, an N=8-bit input vector is formed based on K=4 information bits and N−K=4 frozen bits. The encoder is referred to as a polar encoder, and a decoder configured to decode a polar code is referred to as a polar decoder. In the example shown in FIG. 2, the frozen bits are set to zero. However, the frozen bits may be set to other fixed bit values known to the encoder and decoder. For ease of description, all frozen bits considered in this specification are frozen bits whose value is zero, and may also be generally preferably all-zero frozen bits.

In a process x₁^{N}=u₁^{N}G_{N} of encoding the polar code, some bits in u₁^{N} carry information, and are referred to as a set of information bits, where a set of indexes of the bits is denoted as A. Some other bits are set to a fixed value agreed on by a receive end and a transmit end in advance, and are referred to as a set of fixed bits or a set of frozen bits (frozen bits), where a set of indexes of the bits is indicated by a complementary set A^{c} of A. The process of encoding the polar code is equivalent to x₁^{N}=u_{A}G_{N.}(A)⊕u_{A}_{^{c}}G_{N.}(A^{c}), where G_{N}(A) is a sub-matrix that is in G_{N} and that is obtained from rows corresponding to the indexes in the set A, and G_{N}(A^{C}) is a sub-matrix that is in G_{N} and that is obtained from rows corresponding to the indexes in the set A^{c}. u_{A} is a set of information bits in u₁^{N}, where a quantity of the information bits in the set is K. Generally, various check bits including, but not limited to, a cyclic redundancy check (Cyclic Redundancy Check, CRC for short) bit and a parity check (Parity Check, PC for short) bit, are also included in the set of information bits. u_{A}_{^{c}} is a set of fixed bits in u₁^{N}, a quantity of the fixed bits is (N−K), and the fixed bits are known bits. These fixed bits are usually set to 0. However, the fixed bits may be set to any value provided that the value is agreed on by the receive end and the transmit end in advance. Therefore, the encoding output of the polar code may be simplified as x₁^{N}=u_{A}G_{N}(A), where u_{A} is the set of information bits in u₁^{N}, and u_{A} is a row vector with a length K, to be specific, |A|=K, where |·| indicates a quantity of elements in a set, K is an information block size, G_{N}(A) is a sub-matrix that is in the matrix G_{N} and that is obtained from rows corresponding to the indexes in the set A, and G_{N}(A) is a K×N matrix.

A construction process of the polar code is a selection process of the set A. This determines performance of the polar code. The construction process of the polar code is usually determining, based on a code length N of a mother code, that there are N polarized channels in total, corresponding to N rows of the encoding matrix respectively. Reliability of the polarized channels is calculated. Indexes of first K polarized channels with high reliability are used as elements of the set A, and indexes corresponding to remaining (N−K) polarized channels are used as elements of the set A of indexes of fixed bits. The set A determines locations of the information bits, and the set A^{c} determines locations of the fixed bits. A sequence number of a polarized channel is a location index of an information bit or a fixed bit, that is, a location index in u₁^{N}.

It may be learned from the encoding matrix that the code length of an original polar code (the mother code) is an integer power of 2. During actual application, a polar code of any code length needs to be implemented through rate matching. A puncturing (puncture) or shortening (shorten) solution is used to implement rate matching. During encoding, a mother code that exceeds a target code length is punctured or shortened to achieve the target code length, and during decoding, the target code length is restored to the mother code length through padding.

During polar encoding, an auxiliary bit may be added to an information bit string, to facilitate decoding and error detection or correction at the receiver and improve performance of the polar code. For auxiliary bits in the following embodiments, a redundancy check RC bit is considered to be used as an auxiliary bit, and certainly, other types of auxiliary bits, for example, other auxiliary bits or codes such as a parity check (parity check, PC) bit, a cyclic redundancy check (Cyclic Redundancy Check, CRC) bit, an error detection code (EDC), a checksum bit, a hash function bit, a guaranteed cipher, a repetition code, or an error detection bit, may also be considered to be used for applying the methods disclosed herein. A key to constructing a polar code is to determine to select or allocate sub-channels for information bits and allocate which sub-channels to frozen bits. In some embodiments, the auxiliary bit is considered as a type of information bit, and a more reliable sub-channel is selected or allocated for the auxiliary bit used as the information bit.

A method for constructing a polar code may be an online construction manner. In this case, a parameter for online construction is related to a signal-to-noise ratio SNR, and the transmit end and the receive end cannot obtain an accurate signal-to-noise ratio parameter at the same time (or need to obtain the accurate signal-to-noise ratio parameter by using additional overheads), and the online construction requires additional complexity. In addition, information bit locations need to be separately stored for different encoding lengths and information bit lengths. Alternatively, a construction method irrelevant to a signal-to-noise ratio may be used, for example, construction is performed based on a PW (Polarization Weight, polarization weight) value. A sorting sequence of PW values is a reliability sorting sequence of the polar code, and is for selection of information bits. When an information bit locations are selected based on a PW, the performance can be further improved. Optionally, construction based on a row weight of a generator matrix or a Hamming weight of a sub-channel may further be considered. A hamming weight of a sub-channel is defined herein to be a weight of a row of a generator matrix. In a polar code, a Hamming weight of a sub-channel is related to a row weight of the sub-channel in a generator matrix of the sub-channel (row weight=2\hat{ }(Hamming weight)). Sub-channel reliability may be specified in one or more ordered sequences or the like. A separate and nested sub-channel ordered sequence independent of signal to noise ratio may be calculated for a code length Nₘₐₓ, and an ordered sequence with a shorter code length N is selected from a longer Nₘₐₓ sequence. Alternatively, a plurality of ordered sequences may be calculated based on different mother code lengths Nᵢ, and one of mother code length sequences may be selected for a particular code based on a preferred code length. Another possible option is calculating a plurality of ordered sequences in terms of SNR values and selecting an ordered sequence based on a measured SNR.

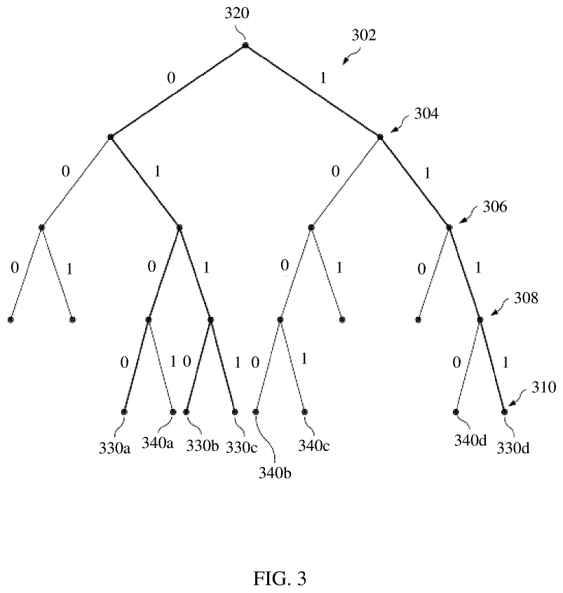

FIG. 3 is a schematic diagram of a decision tree used in an SCL polar decoder, where a width of the decision tree is limited by a maximum given list size. In FIG. 3, a list size L is 4. Five levels of the decision tree are shown: 302, 304, 306, 308, and 310. Although five levels are shown, it should be understood that a decision tree that decodes N bits should have N+1 levels. Each of up to four surviving decoding paths is extended by one bit at each level after the root level 304. Leaf or child nodes of a root node 320 represent possible options for a first bit, and subsequent leaf nodes represent possible options for subsequent bits. For example, a decoding path from the root node 320 to a leaf node 330a represents an estimated codeword bit sequence: 0, 1, 0, 0. At the level 308, a quantity of possible paths is greater than L. Therefore, L paths with highest likelihood (the best path metric (path metric, PM)) are identified, and remaining paths are discarded. In FIG. 3, surviving decoding paths after path sorting and pruning at the level 306 are shown in bold. Similarly, at the level 310, a quantity of possible paths is also greater than L. Therefore, L paths with highest likelihood (the best PM) are identified, and remaining paths are also discarded. In the illustrated example, paths terminating at leaf nodes 330a, 330b, 330c, and 330d represent paths with highest likelihood. Paths terminating at leaf nodes 340a, 340b, 340c, and 340d are discarded paths with lower likelihood.

The following briefly describes an application field and a system architecture to which solutions provided in embodiments of this application are applicable.

Technical solutions in embodiments of this application may be applied to various fields

in which polar encoding is used, for example, the field of data storage, the field of optical network communication, and the field of wireless communication. A wireless communication system to which embodiments of this application are applicable includes, but is not limited to, a long term evolution (long term evolution, LTE) system, a 5G mobile communication system, an LTE and 5G hybrid networking system, and a future communication network system. Certainly, the wireless communication system may also be a non-cellular communication system, for example, Wi-Fi. This is not limited in this application. A scenario to which embodiments of this application are applicable includes, but is not limited to, a communication scenario such as enhanced mobile broadband (enhanced mobile broadband, eMBB), ultra-reliable low-latency communication (ultra reliable low latency communication, URLLC), machine-type communication (machine type communication, MTC), massive machine-type communications (massive machine type communications, mMTC), device-to-device (device-to-device, D2D), the Internet of Vehicles (vehicle to everything, NR V2X), and the Internet of Things (Internet of Things, IoT). Specifically, because embodiments of this application are applicable to a communication scenario with a long code length, and in particular, to a service scenario with a large throughput, for example, a high-definition video service, a large file transfer service, a multimedia service such as virtual reality (virtual reality, VR)/augmented reality (augmented reality, AR), or a service such as an automatic hybrid repeat request (hybrid automatic repeat request, HARQ) of wireless communication.

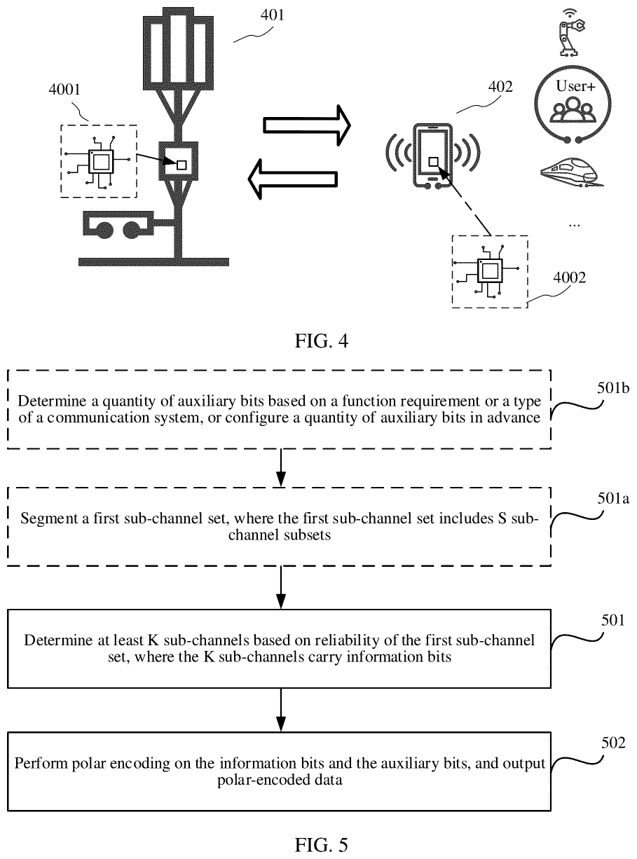

FIG. 4 is a diagram of an architecture of a communication system according to this application. Referring to FIG. 4, at least a sending device and a receiving device are included. Optionally, when the sending device is a terminal device 402, the receiving device is a network device 401. When the sending device is the network device 401, the receiving device is the terminal device 402. The terminal device 402 may communicate with the network device 401 through a wireless or wired uplink (uplink, UL) or downlink (downlink, DL). For example, feasibly, the terminal device may send uplink data to the network device in a UL direction through an uplink physical shared channel (physical uplink shared channel, PUSCH). The network device may send downlink data to the terminal device in a DL direction through a physical downlink shared channel (physical downlink shared channel, PDSCH). For example, when the sending device is the network device 401, if the receiving device is the terminal device 402, the sending device includes an encoder 4001, so that the sending device may perform polar encoding and output an encoded sequence. Generally, the encoded sequence is transmitted to the receiving device through a channel after rate matching, interleaving, and modulation. The receiving device includes a decoder 4002. The receiving device 402 may receive a signal sent by the sending device 401, and decode the received signal.

The terminal device may also be referred to as user equipment (user equipment, UE), a terminal, or the like. The terminal device is a device with a wireless transceiver function, and may be deployed on land, including an indoor device or outdoor device, a handheld device, a wearable device, or an in-vehicle device, or may be deployed on water (for example, on a ship), or may be deployed in the air (for example, on an airplane, a balloon, or a satellite). The terminal device may be a mobile phone (mobile phone), a tablet computer (Pad), a computer with a wireless transceiver function, a virtual reality (Virtual Reality, VR) terminal device, an augmented reality (Augmented Reality, AR) terminal device, a wireless terminal in industrial control (industrial control), a wireless terminal in self-driving (self-driving), a wireless terminal in remote medical (remote medical), a wireless terminal in smart grid (smart grid), a wireless terminal in transportation safety (transportation safety), a wireless terminal in a smart city (smart city), a wireless terminal in a smart home (smart home), or the like. It may be understood that the terminal device may alternatively be a terminal device in a future 5G network, a terminal device in a future evolved public land mobile network (public land mobile network, PLMN), or the like. For ease of description, the following uses a terminal device as an example to describe the method in embodiments of this application.

Optionally, terminal devices may communicate with each other by using a communication technology such as device to device (device to device, D2D), vehicle-to-everything (vehicle-to-everything, V2X), or machine to machine (machine to machine, M2M). A communication method between terminal devices is not limited in embodiments of this application.

The network device may include, but is not limited to, an evolved NodeB (evolved NodeB, eNB, or eNodeB), a NodeB gNB in a 5G mobile communication system, a transmission reception point (transmission reception point, TRP), a base station in a future mobile communication system such as a sixth communication system, and the like. Alternatively, the network device may be a relay station, an access point, an in-vehicle device, a wearable device, a network device in a future evolved public land mobile network (public land mobile network, PLMN), or a base station in a network in which a plurality of technologies are converged or other various other evolved networks.

Optionally, the network device may alternatively be an access node, a wireless relay node, a wireless backhaul node, or the like in a wireless local area network (wireless fidelity, Wi-Fi) system. Optionally, the network device may alternatively be a radio controller in a cloud radio access network (cloud radio access network, CRAN) scenario.

In embodiments of this application, a chip system may include a chip, or may include a chip and another discrete component.

The following describes in detail a polar code encoding/decoding method provided in embodiments of this application.

Based on the foregoing wireless communication network scenario, FIG. 5 shows a communication method for polar code encoding according to an embodiment of this application. This application provides a solution for determining an auxiliary bit of a polar code that is different from the existing solution, to improve decoding accuracy and reduce implementation complexity. Specific steps are as follows:

Step 501: Determine at least K sub-channels based on reliability of a first sub-channel set, where the K sub-channels carry information bits.

S sub-channel subsets are determined based on the first sub-channel set, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers.

Step 502: Perform polar encoding on the information bits and the auxiliary bits, and output polar-encoded data.

The method further includes obtaining the information bits. Optionally, the information bits may be obtained before the at least K sub-channels are determined based on the reliability of the first sub-channel set.

Optionally, the first sub-channel set is a channel set from which a shorten sub-channel is excluded. Specifically, a channel affected by rate matching, for example, shortening, may be excluded from a given channel set to obtain the first sub-channel set. The given channel set may be a channel set with a mother code length of polar code encoding. It should be understood that a sub-channel herein refers to a specific channel. In some cases, a sub-channel and a channel express a same or similar meaning, and are not distinguished.

Optionally, in a specific embodiment, the determining at least K sub-channels based on reliability of a first sub-channel set includes: determining (K+J) sub-channels based on the reliability of the first sub-channel set, where the J sub-channels carry auxiliary bits. To be specific, in this case, not only the K sub-channels are determined, but also the J sub-channels carrying auxiliary bits are determined, where J is a positive integer. Preferably, the selected (K+J) sub-channels are (K+J) sub-channels with highest reliability in the first sub-channel set. It should be noted that the first sub-channel set may be the foregoing channel set from which a shorten sub-channel is excluded, or may be a channel set for which impact of rate matching, such as shortening, is not considered. Optionally, all the Ki sub-channels in the i^{th} sub-channel subset may carry information bits. Certainly, a sub-channel or some sub-channels in the Ki sub-channels in a sub-channel subset or some sub-channel subsets may alternatively carry a frozen bit or a pre-frozen bit. A remaining sub-channel carries the information bits. A possible reason of this is that after rate matching, such a phenomenon occurs in the sub-channel subset or the some sub-channel subsets because sorting based on reliability is changed to sorting based on natural sequence numbers.

Optionally, in a specific embodiment, (Ki+Ji) sub-channels are determined based on reliability of the i^{th} sub-channel subset, where the (Ki+Ji) sub-channels carry information bits and the auxiliary bits. Specifically, reliability of the (Ki+Ji) sub-channels is higher than reliability of a remaining sub-channel in the i^{th} sub-channel subset.

Optionally, in a specific embodiment, the determining at least K sub-channels based on reliability of a first sub-channel set is specifically: determining the K sub-channels based on the reliability of the first sub-channel set. To be specific, the determined quantity of sub-channels is K. Optionally, in the i^{th} sub-channel subset of the S sub-channel subsets, sequence numbers of the Ji sub-channels are greater than a sequence number of a remaining sub-channel in the i^{th} sub-channel channel subset. More specifically, the Ki sub-channels are determined based on reliability of a third sub-channel set. The third sub-channel set is the i^{th} sub-channel subset from which the Ji sub-channels are excluded. The Ki sub-channels carry the information bits. Preferably, reliability of the Ki sub-channels is higher than reliability of a remaining sub-channel in the third sub-channel set.

Optionally, before step 501, step 501a may be further added: segmenting the first sub-channel set, where the first sub-channel set includes the S sub-channel subsets. Specifically, the first sub-channel set may be segmented into the S sub-channel subsets, or may include more than S sub-channel subsets. It is easy to understand that in polar code encoding, frozen bits are usually not discussed because the frozen bits do not carry payload information, but are included in the first sub-channel set; therefore, may be used as a sub-channel subset. The first sub-channel set includes at least S+1 sub-channel subsets. Certainly, for some considerations (for example, pre-freezing), there may be other division of sub-channel subsets, and a quantity of obtained sub-channel subsets may change based on the division

Optionally, a sub-channel or some sub-channels of the K sub-channels carry a pre-frozen bit.

With regard to a value of an auxiliary bit, it is assumed that a total of J auxiliary bits are for non-system auxiliary bits (for error detection/correction), and that a receive end and a transmit end may use an agreed redundancy constant (Redundancy Constant, RC), or it may be considered to use a parity check PC bit as the auxiliary bit. In this case, the value of the auxiliary bit depends on a parity check polynomial (polynomial). Alternatively, it may be considered to use a cyclic redundancy check CRC bit as an extension of this embodiment. Similarly, the value of the auxiliary bit depends on a CRC polynomial (polynomial). In the first case, preferably, the value of the auxiliary bit may be 0 or 1. Specifically, if there is a 4-bit auxiliary bit, a value of the auxiliary bit may be determined by 0 or 1. Optionally, the value of the auxiliary bit may not be all 0 or may not be all 1, values, such as 0001, 0101, 0110, 0111, and 1010, all fall within the scope of this application. Alternatively, a value of the auxiliary bit is determined based on a part or all of a terminal identifier UE-ID, or a value of the auxiliary bit is determined based on a part or all of a base station identifier BS-ID. Alternatively, a value of the auxiliary bit is determined based on a part or all of the terminal identifier UE-ID and a part or all of the base station identifier BS-ID.

Optionally, before step 501, step 501b may be further added: determining, based on a function requirement or a type of the communication system, a quantity of non-system auxiliary bits, that is, a quantity of the auxiliary bits described in this embodiment. Certainly, in terms of quantity design, it may be considered that a quantity of auxiliary bits is directly given in the communication system, to facilitate engineering implementation. Therefore, it may be understood that determining a total quantity of auxiliary bits is not necessary during implementation. In a design of this embodiment, generally, a total quantity J of the auxiliary bits may be determined based on a quantity T of times of checking a check result of the auxiliary bits during polar decoding, and T is a positive integer. The list size L during decoding is mentioned above. Generally, if T is less than or equal to L, false alarm rate performance of the code is better when T is set to a smaller value. Specifically, in a specific case or some cases, the total quantity J of the auxiliary bits is greater than or equal to log₂(T). Alternatively, the total quantity J of the auxiliary bits is greater than or equal to log₂(T*CN), and CN is a quantity of candidate locations that need to be blindly detected. Alternatively, the total quantity J of the auxiliary bits is greater than or equal to Σ_{i∈s}(log(Tᵢ)+Cᵢ), and Cᵢ is an integer. Alternatively, the total quantity J of the auxiliary bits is a nonnegative integer power of 2. More specifically, in a communication system that does not require blind detection, the total quantity J of the auxiliary bits is greater than or equal to log₂(T), for example, J=log₂(T)+C, and C is a constant. Alternatively, in a communication system that requires blind detection, the total quantity J of the auxiliary bits is greater than or equal to log₂(T*CN), for example, J=log₂(T*CN)+C, C is a constant, and ('N is a quantity of candidate locations that need to be blindly detected, that is, a quantity of candidate combinations of locations and code lengths/code rates that need to be blindly detected on a channel in the communication system, for example, a maximum quantity of the candidate combinations. Alternatively, in an asymmetric block-combined (Asymmetric Block-combined, ABC) polar code communication system, the total quantity J of the auxiliary bits is greater than or equal to Σ_{i∈s}(log(Tᵢ)+Cᵢ), for example J=Σ_{i∈s}(log(Tᵢ)+Cᵢ), and Cᵢ is a constant. For an ABC polar code, auxiliary bits may be inserted at specific locations, to divide the entire polar code into S blocks. All the blocks may be different in terms of Tᵢ and Cᵢ. Alternatively, in a communication system with low power consumption, the total quantity J of the auxiliary bits is a nonnegative integer power of 2. For example, when the auxiliary bit is an RC bit, to accelerate convergence of a flip-SC decoder, J may be rounded up or down to 2^{x} to obtain J′, where x may be 0 or a positive integer. To be specific, a value closest to J may be selected from [2, 4, 8, 16 . . . ], that is, J is rounded down or J is rounded up to a specific number in [2, 4, 8, 16 . . . ]. Certainly, there are many rounding manners, and J may be rounded in a common round-off manner, and only a non-negative integer is taken as a result. It may be understood that the specific quantity J of auxiliary bits determined based on the foregoing formula shall also fall within the protection scope of this application, and is not listed one by one again. The foregoing methods for determining quantities in different scenarios may be used with reference to each other, or are interchangeable. For example, in a communication system without blind detection, the total quantity J of the auxiliary bits may be greater than or equal to log₂(T*CN), or the total quantity J may be greater than or equal to Σ_{i∈s}(log(Tᵢ)+Cᵢ). From a perspective of simplified engineering implementation, a method for determining a quantity J of auxiliary bits may be used for compatibility with a plurality of different scenarios. For example, the total quantity J is a nonnegative integer power of 2.

Optionally, C in the foregoing formula is a integer constant, and may have a value such as ±0, ±1, ±2, ±3, ±4, ±5, ±6, ±7, ±8, ±9, ±10, ±11, ±12, ±13, ±14, ±15, ±16, . . . .

The following continues to describe and explain the technical solutions of this application by using specific examples.

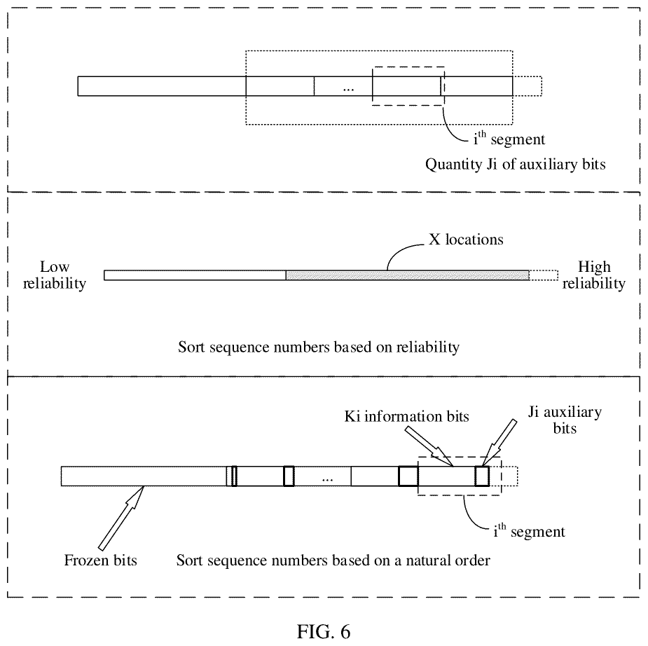

As shown in FIG. 6, in a possible specific example, the total quantity J of the auxiliary bits and the quantity S of segments of the sub-channel set are learned, to determine quantities J₁, J₂, . . . , Jₛ of auxiliary bits of all the segments. In a possible case, there may be S+1 segments, and an extra segment is a sub-channel set for placing frozen bits. In another possible case, there may alternatively be S+2 segments, one extra segment is a sub-channel set for placing frozen bits, and the other extra segment is a rate-matched sub-channel set. Other cases are not listed one by one. It may be understood that this embodiment and the method in this application focus on sub-channel segments to which auxiliary bits are added. Therefore, division into S segments is used as an example for description. A quantity of segments is related to a segmented sub-channel set, and it should not be understood that a quantity of segments is strictly limited, which is also applicable to the following examples. Details are not described again. In addition, the quantity J of auxiliary bits and the values may be determined by referring to the foregoing method.

X (or represented as K+J) sub-channel locations are selected in descending order of reliability in a given sub-channel set for placing auxiliary bits and information bits. The given sub-channel set may be a set of sub-channel locations from which rate matching (for example, shortening or puncturing) or impact of rate matching has been excluded or may be a sub-channel set with a length of a mother code of the polar code.

Then, the selected X locations are allocated to S segments based on physical addresses (or sequence numbers of the sub-channel) of the selected sub-channel locations, where quantities of sub-channels in all the segments are X₁, X₂, . . . , Xₛ, quantities of auxiliary bits in all the segments are J₁, J₂, . . . , Jₛ, and quantities of information bits in all the segments are X₁-J₁, X₂-J₂, . . . , Xₛ-Jₛ. In a possible case, if Xᵢ is less than or equal to Jᵢ, no information bit is allocated to the segment (the i^{th} segment). In another possible case, the quantity S of segments in non-ABC-Polar is 1. Finally, information bits and auxiliary bits are placed in each segment based on a sequence of physical addresses (or sequence numbers of sub-channels), and the information bits are placed before the auxiliary bits.

Referring to the processing process shown in FIG. 6, in another possible specific example, the total quantity J of the auxiliary bits and the quantity S of segments are learned, to determine quantities J₁, J₂, . . . , Jₛ of auxiliary bits of all the segments. The quantity J of auxiliary bits and the values may be determined by referring to the foregoing method, and details are not described again. K sub-channel locations are selected in descending order of reliability in a given sub-channel set for placing information bits. The given sub-channel set may be a set of sub-channel locations from which rate matching (for example, shortening or puncturing) or impact of rate matching has been excluded or may be a sub-channel set with a length of a mother code of the polar code. Then, in a possible case, information bit locations are determined in each segment based on the selected K sub-channel locations, and a quantity of sub-channels in which information bits are determined to be placed in each segment is counted. When a quantity Kᵢ of information bit locations selected in a segment plus a quantity Jᵢ of auxiliary bits allocated to the segment is equal to a preset length Xᵢ of the segment, other unselected locations in the segment are frozen, or are for placing frozen bits (a quantity of which is equal to the quantity of auxiliary bits of the segment). The selected K locations are allocated to the S segments based on physical addresses (or sequence numbers of sub-channels) of selected sub-channel locations. Quantities of information bits in all the segments are K₁, K₂, . . . , Kₛ, and quantities of auxiliary bits in all the segments are J₁, J₂, . . . , Jₛ. In a possible case, the quantity S of segments in non-ABC-Polar is 1.

Kᵢ+Jᵢ sub-channel locations are selected from a sub-channel set of each segment in descending order of reliability, for placing information bits and auxiliary bits. The sub-channel set of the segment comes from the foregoing given sub-channel set. To be specific, a sub-channel set of each segment is a set of sub-channel locations from which rate matching (for example, shortening or puncturing) or impact of rate matching has been excluded. Finally, the information bits and the auxiliary bits are placed in Kᵢ+Jᵢ sub-channel locations in each segment based on a sequence of physical addresses (or in ascending order of sequence numbers of sub-channels), and the information bits are placed at first locations in the Kᵢ+Jᵢ sub-channel locations, and the auxiliary bits are placed at last locations in the Kᵢ+Jᵢ sub-channel locations.

Similarly, referring to the processing process shown in FIG. 6, in another possible specific example, the total quantity J of the auxiliary bits and the quantity S of segments are learned, to determine quantities J₁, J₂, . . . , Jₛ of auxiliary bits of all the segments. The quantity J of auxiliary bits and the values may be determined by referring to the foregoing method, and details are not described again. K sub-channel locations are selected in descending order of reliability in a given sub-channel set. The given sub-channel set may be a set of sub-channel locations from which rate matching (for example, shortening or puncturing) or impact of rate matching has been excluded or may be a sub-channel set with a length of a mother code of the polar code. Then, in a possible case, a quantity of information bits is determined in each segment based on the selected K sub-channel locations, and a quantity of sub-channels in which information bits are determined to be placed in each segment is counted. When a quantity Kᵢ of information bit locations selected in a segment plus a quantity Jᵢ of auxiliary bits allocated to the segment is equal to a preset length Xᵢ of the segment, other unselected locations in the segment are frozen, or are for placing frozen bits, a quantity of which is equal to the quantity of auxiliary bits of the segment. The selected K locations are allocated to the S segments based on physical addresses (or sequence numbers of sub-channels) of selected sub-channel locations. Quantities of information bits in all the segments are K₁, K₂, . . . , Kₛ, and quantities of auxiliary bits in all the segments are J₁, J₂, . . . , Jₛ. In a possible case, the quantity S of segments in non-ABC-Polar is 1.

Jᵢ sub-channel locations are selected from a sub-channel set of each segment in descending order of physical locations of the sub-channels (or in descending order of natural sequence numbers of the sub-channels), for placing auxiliary bits. The sub-channel set of the segment comes from the foregoing given sub-channel set. To be specific, a sub-channel set of each segment is a set of sub-channel locations from which rate matching (for example, shortening or puncturing) or impact of rate matching has been excluded. Then, Kᵢ sub-channel locations are selected in descending order of reliability from the sub-channel set of each segment from which the Jᵢ locations that have been selected are excluded. The information bits are padded at the information bit locations, and the auxiliary bits are padded at auxiliary bit locations. From a perspective of a physical location relationship, sequence numbers of sub-channels for placing the auxiliary bits are after sequence numbers of sub-channels for placing the information bits.

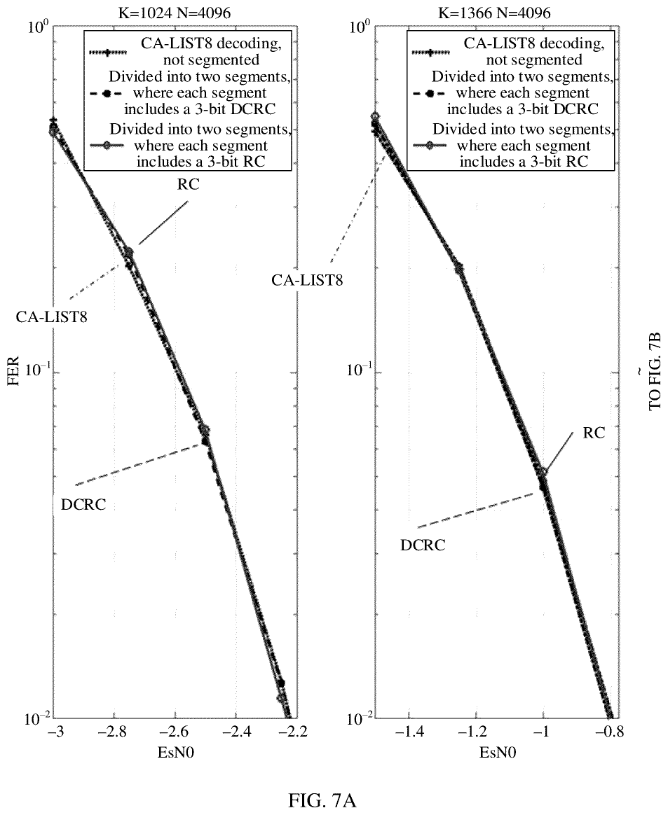

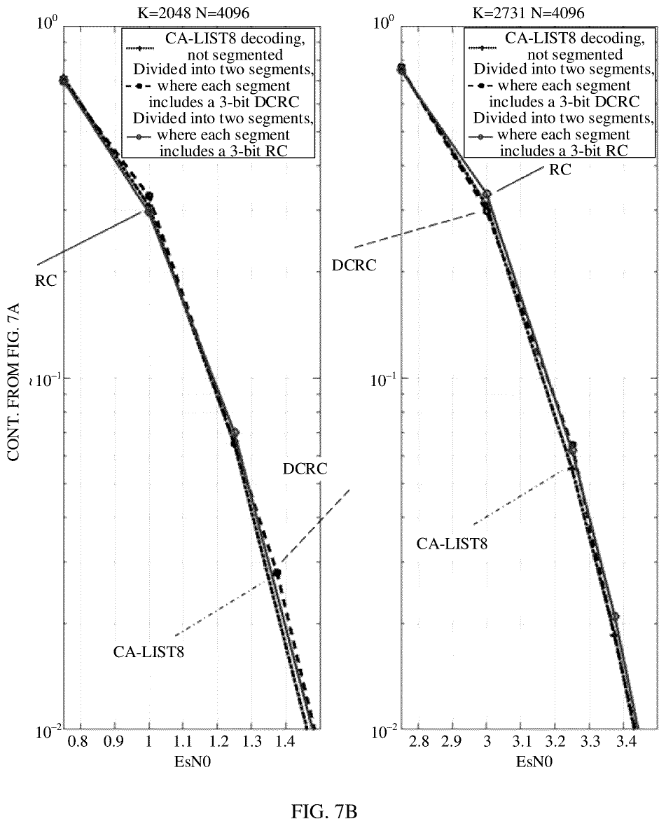

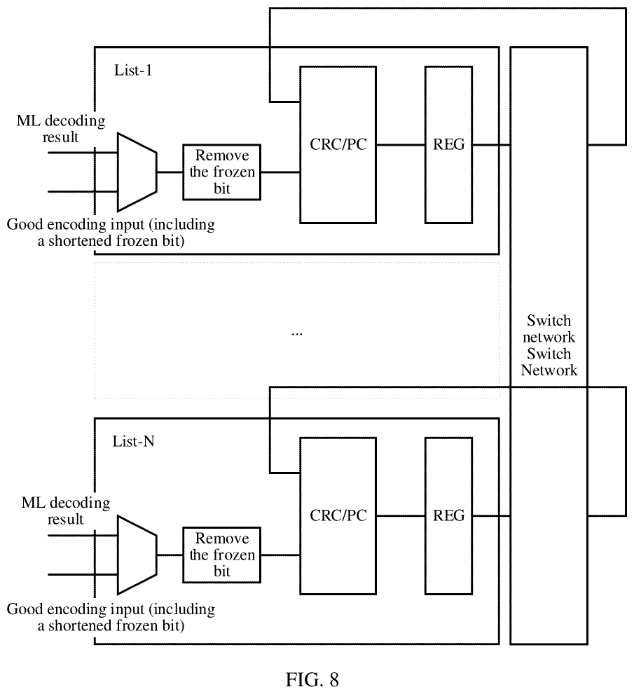

FIG. 7A and FIG. 7B show FER performance of three polar codes under conditions such as different quantities K of information bits and a same code length N. A CA-LIST8 curve represents performance of a polar code that is not segmented, and no extra auxiliary bit is added to the code, where L=8. A DCRC curve represents performance of a polar code to which six CRC auxiliary bits are added (based on the polar code of CA-LIST8). The code is divided into two segments, and each segment includes a 3-bit distributed CRC. An RC curve represents performance of a polar code to which six redundancy constant RC auxiliary bits are added (based on the polar code of CA-LIST8). The code is divided into two segments, each segment includes a 3-bit RC, and the redundancy constant is padded with a signal 0. Based on simulation results, the three are very close in terms of FER performance, and there is no significant difference in a simulation range. In general, under specific conditions, using a J-bit redundancy constant RC or a parity check PC bit+X systematic cyclic redundancy check CRC bits and using a (J+X)-bit CRC bit can achieve same or similar effects in terms of false alarm rate FAR performance and frame error rate FER performance. FIG. 8 is a schematic diagram of an auxiliary-bit calculation circuit commonly used in an existing LIST decoder. After the solution disclosed in this application is used, complexity of a decoder can be effectively reduced, overheads caused by auxiliary bit calculation can be reduced, and area overheads of the decoder can be reduced. In a solution in which a redundant constant RC is used, area overheads can be reduced by about 5% to 10% for the decoder. When a PC bit is used as the auxiliary bit in the solution, the PC bit may be used for self-checking of a decoding result. Generally, calculation difficulty of the PC bit is lower than that of a CRC bit. A frozen-bit removing module in the figure may be excluded. When CRC calculation is switched to PC calculation, overheads of the decoder can be reduced by about 2%. It can be learned that, in a specific application scenario, decoding overheads are reduced in the solution disclosed in this application, but good beneficial effects are achieved without sacrificing code performance.

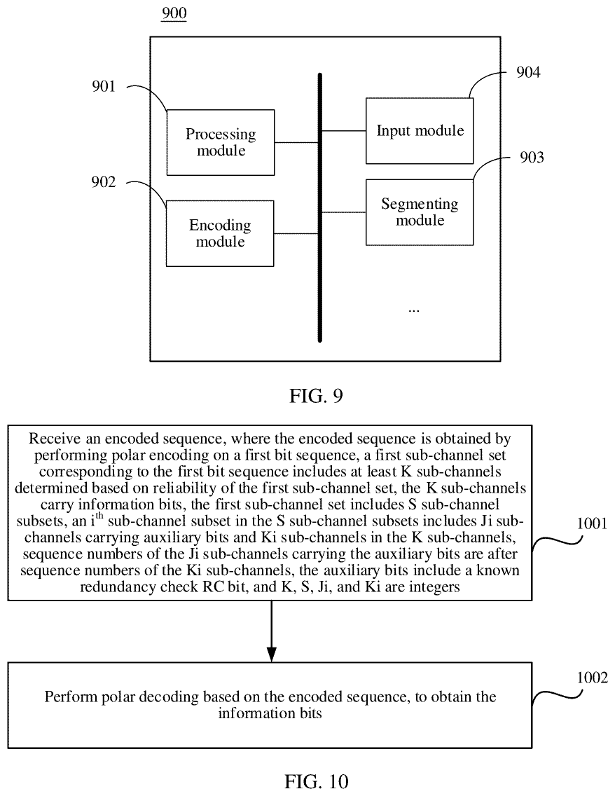

Based on the communication method disclosed above, as shown in FIG. 9, this application further provides a communication apparatus 900 for polar encoding. The communication apparatus 900 is configured to perform the communication method disclosed above and the method described in the possible specific examples. The communication apparatus 900 includes a processing module 901 and an encoding module 902.

The processing module 901 is configured to determine at least K sub-channels based on reliability of a first sub-channel set, where the K sub-channels carry information bits.

The encoding module 902 is configured to perform polar encoding on the information bits and auxiliary bits, and output polar-encoded data.

S sub-channel subsets are determined based on the first sub-channel set, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers.

Optionally, the first sub-channel set is a channel set from which a shorten sub-channel is excluded. Specifically, a channel affected by rate matching, for example, shortening, may be excluded from a given channel set to obtain the first sub-channel set. The given channel set may be a channel set with a mother code length of polar code encoding. It should be understood that a sub-channel herein refers to a specific channel. In some cases, a sub-channel and a channel express a same or similar meaning, and are not distinguished.

Optionally, in a specific embodiment, the processing module 901 is further configured to determine (K+J) sub-channels based on the reliability of the first sub-channel set, where the J sub-channels carry auxiliary bits. To be specific, in this case, not only the K sub-channels are determined, but also the J sub-channels carrying auxiliary bits are determined, where J is a positive integer. Preferably, the selected (K+J) sub-channels are (K+J) sub-channels with highest reliability in the first sub-channel set. It should be noted that the first sub-channel set may be the foregoing channel set from which a shorten sub-channel is excluded, or may be a channel set for which impact of rate matching, such as shortening, is not considered. Optionally, all the Ki sub-channels in the i^{th} sub-channel subset may carry information bits. Certainly, a sub-channel or some sub-channels in the Ki sub-channels in sub-channel subset or some sub-channel subsets may alternatively carry a frozen bit or a pre-frozen bit. A remaining sub-channel carries the information bits. A possible reason of this is that after rate matching, such a phenomenon occurs in the sub-channel subset or the some sub-channel subsets because sorting based on reliability is changed to sorting based on natural sequence numbers.

Optionally, in a specific embodiment, the processing module 901 is further configured to determine (Ki+Ji) sub-channels based on reliability of the i^{th} sub-channel subset, where the (Ki+Ji) sub-channels carry information bits and the auxiliary bits. Specifically, reliability of the (Ki+Ji) sub-channels is higher than reliability of a remaining sub-channel in the i^{th} sub-channel subset.

Optionally, in a specific embodiment, the processing module 901 is further configured to determine the K sub-channels based on the reliability of the first sub-channel set. To be specific, the determined quantity of sub-channels is K. Optionally, in the i^{th} sub-channel subset of the S sub-channel subsets, sequence numbers of the Ji sub-channels are greater than a sequence number of a remaining sub-channel in the i^{th} sub-channel subset. More specifically, the Ki sub-channels are determined based on reliability of a third sub-channel set. The third sub-channel set is the i^{th} sub-channel subset from which the Ji sub-channels are excluded. The Ki sub-channels carry the information bits. Preferably, reliability of the Ki sub-channels is higher than reliability of a remaining sub-channel in the third sub-channel set.

Optionally, the communication apparatus 900 further includes a segmenting module 903, configured to segment the first sub-channel set, where the first sub-channel set includes the S sub-channel subsets. Specifically, the first sub-channel set may be segmented into the S sub-channel subsets, or may include more than S sub-channel subsets. It is easy to understand that in polar code encoding, frozen bits are usually not discussed because the frozen bits do not carry payload information, but are included in the first sub-channel set, and therefore, may be used as a sub-channel subset. The first sub-channel set includes at least S+1 sub-channel subsets. Certainly, for some considerations (for example, pre-freezing), there may be other division of sub-channel subsets, and a quantity of obtained sub-channel subsets may change based on the division

Optionally, a sub-channel or some sub-channels of the K sub-channels carry a pre-frozen bit.

With regard to a value of an auxiliary bit, assuming that a total of J auxiliary bits are used for non-system auxiliary bits (used for error detection/correction), and a receive end and a transmit end may use an agreed redundancy constant (Redundancy Constant, RC). Alternatively, it may be considered to use a parity check PC bit as the auxiliary bit. In this way, the value of the auxiliary bit depends on a parity check polynomial (polynomial). Alternatively, it may be considered to use a cyclic redundancy check CRC bit as an extension of this embodiment. Similarly, the value of the auxiliary bit depends on a CRC polynomial (polynomial). In the first case, preferably, a value of the auxiliary bit is 0 or 1. Alternatively, a value of the auxiliary bit is determined based on a part or all of a terminal identifier UE-ID, or a value of the auxiliary bit is determined based on a part or all of a base station identifier BS-ID. Alternatively, a value of the auxiliary bit is determined based on a part or all of the terminal identifier UE-ID and a part or all of the base station identifier BS-ID.

Optionally, the communication apparatus 900 further includes an input module 904. On the one hand, the input module 904 may be configured to obtain information bits. Optionally, the input module 904 may obtain the information bits before the at least K sub-channels are determined based on the reliability of the first sub-channel set. On the other hand, the input module 904 may be configured to obtain a quantity of auxiliary bits, for example, determine a quantity of non-system auxiliary bits based on a function requirement or a type of the communication system, that is, the quantity of auxiliary bits in this embodiment. Certainly, in terms of quantity design, it may be considered that the input module 904 directly obtains the quantity of auxiliary bits, to facilitate engineering implementation. Therefore, it may be understood that determining a total quantity of auxiliary bits is not necessary during implementation. Alternatively, the quantity of auxiliary bits may be determined through the processing module 901. In a possible implementation, the quantity of auxiliary bits is preset in the processing module 901. In a design of this embodiment, generally, a total quantity J of the auxiliary bits may be determined based on a quantity T of times of checking a check result of the auxiliary bits during polar decoding, and T is a positive integer. A list size L during decoding is mentioned above. Generally, if T is less than or equal to L, false alarm rate performance of the code is better when T is set to a smaller value. Specifically, in a specific case or some cases, the total quantity J of the auxiliary bits is greater than or equal to log₂(T). Alternatively, the total quantity J of the auxiliary bits is greater than or equal to log₂(T*CN), and CN is a quantity of candidate locations that need to be blindly detected. Alternatively, the total quantity J of the auxiliary bits is greater than or equal to Σ_{i∈s}(log(Tᵢ)+Cᵢ), and Cᵢ is an integer. Alternatively, the total quantity J of the auxiliary bits is a nonnegative integer power of 2. More specifically, in a communication system that does not require blind detection, the total quantity J of the auxiliary bits is greater than or equal to log₂(T), for example, J=log₂(T)+C, and C is a constant. Alternatively, in a communication system that requires blind detection, the total quantity J of the auxiliary bits is greater than or equal to log₂(T*CN), for example, J=log₂(T*CN)+C, C is a constant, and CN is a quantity of candidate locations that need to be blindly detected, that is, a quantity of candidate combinations of locations and code lengths/code rates that need to be blindly detected on a channel in the communication system, for example, a maximum quantity of the candidate combinations. Alternatively, in an asymmetric block-combined (Asymmetric Block-combined, ABC) polar code communication system, the total quantity J of the auxiliary bits is greater than or equal to Σ_{i∈s}(log(Tᵢ)+Cᵢ), for example J=Σ_{i∈s}(log(Tᵢ)+Cᵢ), and Cᵢ is a constant. For an ABC polar code, auxiliary bits may be inserted at specific locations, to divide the entire polar code into S blocks. All the blocks may be different in terms of Tᵢ and Cᵢ. Alternatively, in a communication system with low power consumption, the total quantity J of the auxiliary bits is a nonnegative integer power of 2. For example, when the auxiliary bit is an RC, to accelerate convergence of a flip-SC decoder, J may be rounded up or down to 2^{x} to obtain J′, where x may be 0 or a positive integer. To be specific, a value closest to J may be selected from [2, 4, 8, 16 . . . ], that is, J is rounded down or J is rounded up to a specific number in [2, 4, 8, 16 . . . ]. Certainly, there are many rounding manners, and J may be rounded in a common round-off manner, and only a non-negative integer is taken as a result. It may be understood that the specific quantity J of auxiliary bits determined based on the foregoing formula shall also fall within the protection scope of this application, and is not listed one by one again. The foregoing methods for determining quantities in different scenarios may be used with reference to each other, or are interchangeable. For example, in a communication system without blind detection, the total quantity J of the auxiliary bits may be greater than or equal to log₂(T*CN), or the total quantity J may be greater than or equal to Σ_{i∈s}(log(Tᵢ)+Cᵢ). From a perspective of simplified engineering implementation, a method for determining a quantity J of auxiliary bits may be used for compatibility with a plurality of different scenarios. For example, the total quantity J is a nonnegative integer power of 2.

Optionally, C in the foregoing formula is a integer constant, and may have a value such as ±0, ±1, ±2, ±3, ±4, ±5, ±6, ±7, ±8, ±9, ±10, ±11, ±12, ±13, ±14, ±15, ±16, . . . .

The communication apparatus 900 may be further configured to implement the solutions described in the foregoing specific examples. In this case, functions implemented by functional modules of the communication apparatus 900 may be learned with reference to the solutions described in the foregoing specific examples and functions of the modules of the communication apparatus 900. Details are not described again.

Based on similar concepts of polar encoding and auxiliary bits determining, as shown in FIG. 10, embodiments of this application further provide a communication method for polar decoding. This application provides a solution for determining an auxiliary bit of a polar code that is different from the existing solution, to improve decoding accuracy and reduce implementation complexity. Specific steps are as follows:

Step 1001: Receive an encoded sequence, where the encoded sequence is obtained by performing polar encoding on a first bit sequence, a first sub-channel set corresponding to the first bit sequence includes at least K sub-channels determined based on reliability of the first sub-channel set, the K sub-channels carry information bits, the first sub-channel set includes S sub-channel subsets, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers.

Step 1002: Perform polar decoding based on the encoded sequence, to obtain the information bits.

Optionally, the first sub-channel set is a channel set from which a shorten sub-channel is excluded. Specifically, a channel affected by rate matching, for example, shortening, may be excluded from a given channel set to obtain the first sub-channel set. The given channel set may be a channel set with a mother code length of polar code encoding. It should be understood that a sub-channel herein refers to a specific channel. In some cases, a sub-channel and a channel express a same or similar meaning, and are not distinguished.

Optionally, in a specific embodiment, the determining at least K sub-channels based on reliability of a first sub-channel set includes: determining (K+J) sub-channels based on the reliability of the first sub-channel set, where the J sub-channels carry auxiliary bits. To be specific, in this case, not only the K sub-channels are determined, but also the J sub-channels carrying auxiliary bits are determined, where J is a positive integer. Preferably, the selected (K+J) sub-channels are (K+J) sub-channels with highest reliability in the first sub-channel set. It should be noted that the first sub-channel set may be the foregoing channel set from which a shorten sub-channel is excluded, or may be a channel set for which impact of rate matching, such as shortening, is not considered. Optionally, all the Ki sub-channels in the i^{th} sub-channel subset may carry information bits. Certainly, a sub-channel or some sub-channels in the Ki sub-channels in a sub-channel subset or some sub-channel subsets may alternatively carry a frozen bit or a pre-frozen bit. A remaining sub-channel carries the information bits. A possible reason of this is that after rate matching, such a phenomenon occurs in the sub-channel subset or the some sub-channel subsets because sorting based on reliability is changed to sorting based on natural sequence numbers.

Optionally, in a specific embodiment, (Ki+Ji) sub-channels are determined based on reliability of the i^{th} sub-channel subset, where the (Ki+Ji) sub-channels carry information bits and the auxiliary bits. Specifically, reliability of the (Ki+Ji) sub-channels is higher than reliability of a remaining sub-channel in the i^{th} sub-channel subset.

Optionally, in a specific embodiment, determining the at least K sub-channels based on the reliability of the first sub-channel set is specifically: determining the K sub-channels based on the reliability of the first sub-channel set. To be specific, the determined quantity of sub-channels is K. Optionally, in the i^{th} sub-channel subset of the S sub-channel subsets, sequence numbers of the Ji sub-channels are greater than a sequence number of a remaining sub-channel in the i^{th} sub-channel subset. More specifically, the Ki sub-channels are determined based on reliability of a third sub-channel set. The third sub-channel set is the i^{th} sub-channel subset from which the Ji sub-channels are excluded. The Ki sub-channels carry the information bits. Preferably, reliability of the Ki sub-channels is higher than reliability of a remaining sub-channel in the third sub-channel set.

Specifically, the first sub-channel set may be segmented into the S sub-channel subsets, or may include more than S sub-channel subsets. It is easy to understand that in polar code encoding, frozen bits are usually not discussed because the frozen bits do not carry payload information, but are included in the sub-channel set, and therefore, may be used as a sub-channel subset. The first sub-channel set includes at least S+1 sub-channel subsets. Certainly, for some considerations (for example, pre-freezing), there may be other division of sub-channel subsets, and a quantity of obtained sub-channel subsets may change based on the division

Optionally, a sub-channel or some sub-channels of the K sub-channels carry a pre-frozen bit.

With regard to a value of an auxiliary bit, assuming that a total of J auxiliary bits are used for non-system auxiliary bits (used for error detection/correction), and a receive end and a transmit end may use an agreed redundancy constant (Redundancy Constant, RC). Alternatively, it may be considered to use a parity check PC bit as the auxiliary bit. Optionally, the decoder side may determine, based on a function requirement or a type of the communication system, a quantity of non-system auxiliary bits, that is, a quantity of the auxiliary bits described in this embodiment. Certainly, in terms of quantity design, it may be considered that a transmit end and a receive end in the communication system directly agree on a quantity of auxiliary bits, to facilitate engineering implementation. Therefore, it may be understood that determining a total quantity of auxiliary bits is not necessary during implementation. For a specific method for determining a value of an auxiliary bit and a specific method for calculating a quantity of auxiliary bits, refer to the foregoing descriptions in the polar encoding.

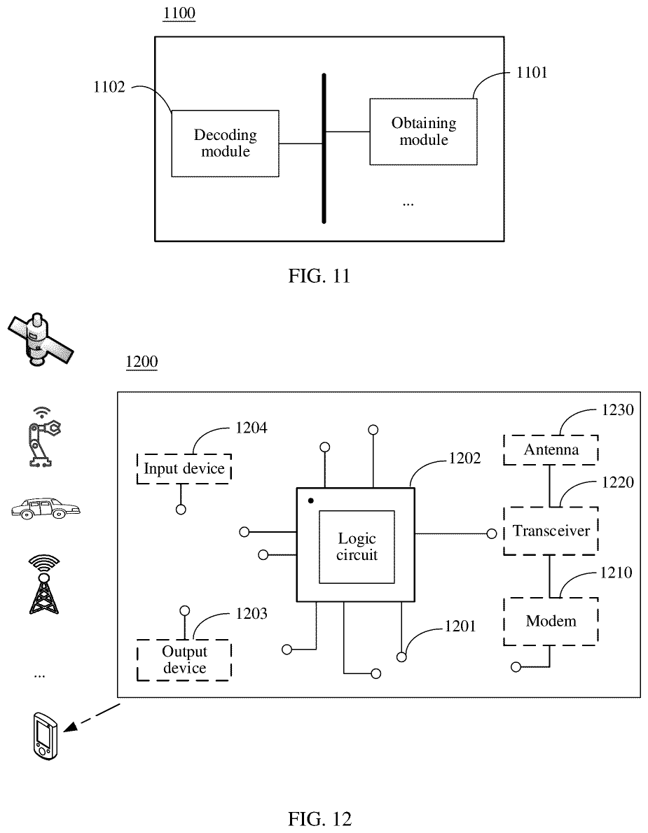

Based on the communication method for polar decoding disclosed above, as shown in FIG. 11, this application further provides a communication apparatus 1100 for polar decoding. The communication apparatus 1100 is configured to perform the communication method disclosed above and the method described in the possible specific examples. The communication apparatus 1100 includes an obtaining module 1101 and a decoding module 1102.

The obtaining module 1101 is configured to obtain an encoded sequence, where the encoded sequence is obtained by performing polar encoding on a first bit sequence, a first sub-channel set corresponding to the first bit sequence includes at least K sub-channels determined based on reliability of the first sub-channel set, the K sub-channels carry information bits, the first sub-channel set includes S sub-channel subsets, an i^{th} sub-channel subset in the S sub-channel subsets includes Ji sub-channels carrying auxiliary bits and Ki sub-channels in the K sub-channels, sequence numbers of the Ji sub-channels carrying the auxiliary bits are after sequence numbers of the Ki sub-channels, the auxiliary bits include a known redundancy check RC bit, and K, S, Ji, and Ki are integers.

The decoding module 1102 is configured to perform polar decoding based on the encoded sequence, to obtain the information bits.

Optionally, with regard to a value of an auxiliary bit, assuming that a total of J auxiliary bits are used for non-system auxiliary bits (used for error detection/correction), and a receive end and a transmit end may use an agreed redundancy constant (Redundancy Constant, RC), for example, a constant 0. Alternatively, it may be considered to use a parity check PC bit as the auxiliary bit. Optionally, the obtaining module 1101 is further configured to determine, based on a function requirement or a type of the communication system, a quantity of non-system auxiliary bits, that is, a quantity of the auxiliary bits described in this embodiment. Certainly, in terms of quantity design, it may be considered that a transmit end and a receive end in the communication system directly agree on a quantity of auxiliary bits, to facilitate engineering implementation. Therefore, it may be understood that determining a total quantity of auxiliary bits is not necessary during implementation. For a specific method for determining a value of an auxiliary bit and a specific method for calculating a quantity of auxiliary bits, refer to the foregoing descriptions in the polar encoding.

Optionally, for other functions of the communication apparatus 1100 and modules of the communication apparatus 1100, refer to descriptions in specific optional implementations of the foregoing communication method for polar decoding. Details are not described again.

Based on same concepts of polar encoding, decoding, and auxiliary bits determining, as shown in FIG. 12, embodiments of this application further provide a polar code communication apparatus 1200. The polar code communication apparatus 1200 may be configured to perform the foregoing polar encoding method or polar decoding method, and perform the methods described in specific examples. The method may be partially or entirely implemented by hardware, or the method may be partially or entirely implemented by software. For example, specifically, the method may be implemented by a combination of hardware and software. Optionally, when the foregoing method is mainly implemented by hardware, the polar code communication apparatus 1200 includes a communication interface 1201 and a logic circuit 1202. The communication interface 1201 is configured to obtain to-be-coded bits, where the to-be-coded bits include information bits, and the information bits herein may be payload (payload) bits, or configured to obtain an encoded sequence, where the encoded sequence is obtained after polar encoding is performed on a first bit sequence. The logic circuit 1202 is configured to perform the foregoing communication method for polar encoding. For details, refer to the descriptions in the foregoing embodiments. The logic circuit 1202 performs functions such as determining at least K sub-channels based on reliability of a first sub-channel set, and performing polar encoding on the information bits and the auxiliary bits. Alternatively, the logic circuit 1202 is configured to perform the foregoing communication method for polar decoding, and perform functions such as performing polar decoding based on an encoded sequence to obtain information bits. The logic circuit 1202 may further perform the methods described in the foregoing specific examples. The communication interface 1201 (which may not be the same interface 1201 that implements the foregoing obtaining function) is further configured to output polar-encoded data or output polar-decoded bits.

Further, the encoded data output by the communication apparatus 1200 is modulated by a modulator 1210 and then output to a transceiver 1220. The transceiver 1220 performs corresponding processing (including, but not limited to, digital-to-analog conversion and/or frequency conversion processing) on the modulated sequence, and then send the sequence through an antenna 1230. Correspondingly, during decoding, a signal of an air interface is received through the antenna 1230, and then, transmitted through the transceiver 1220 to a demodulator 1210 for processing. The signal that has been processed by the demodulator 1210 is transmitted to the logic circuit 1202 through the communication interface 1201 for decoding. It is easy to understand that, from a perspective of product integration, when some conditions permit, the modulator/demodulator 1210 and the transceiver 1220 may be a function implementation module or a physical implementation unit, or the transceiver 1220 and the antenna 1230 may be a function implementation module or a physical implementation unit. Similarly, one physical entity may be used to implement functions of the modulator and the demodulator. For example, 1210 may also be a modulator/demodulator, and the logic circuit 1202 may also have a decoding function. Specifically, during specific implementation, the communication apparatus 1200 may be a chip or an integrated circuit.

In an optional implementation, the communication apparatus 1200 further includes an output device 1203 and an input device 1204. For example, the input device 1204 is a device such as a (virtual) keyboard, a microphone, or a joystick, and the output device 1203 is a device such as a display screen or a speaker (speaker). A person skilled in the art may figure out that the communication apparatus 1200 may be a mobile phone, a base station, an automobile, an industrial robot, a satellite, a network server, a desktop computer, a portable computer, a tablet computer, a wireless terminal, an embedded device, a chip system, or a device having a similar structure or circuit in FIG. 12. In addition, the composition structure shown in FIG. 12 does not constitute a limitation on the communication apparatus. In addition to the components shown in FIG. 12, the communication apparatus may include more or fewer components than those shown in the figure, or combine some components, or have different component arrangements.

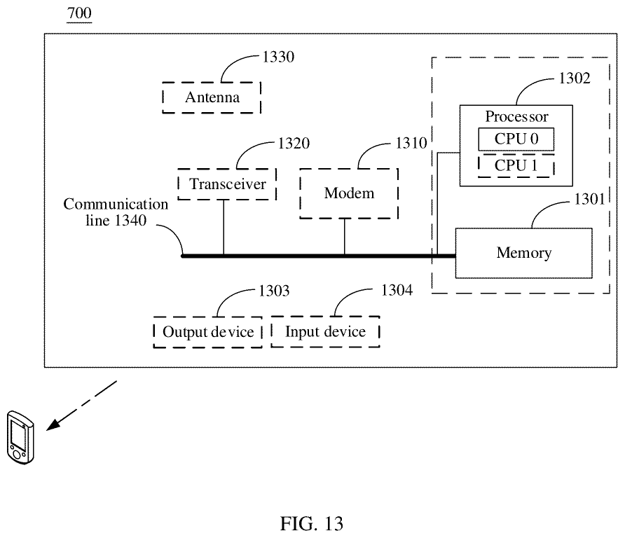

Optionally, when the foregoing method is partially or entirely implemented by software, as shown in FIG. 13, a polar code communication apparatus 1300 includes a memory 1301 and a processor 1302. The memory 1301 is configured to store a program. The processor 1302 is configured to execute a part or all of the program stored in the memory 1301. When the program is executed, the polar code communication apparatus 1300 can perform the foregoing polar encoding method or the polar decoding method, and perform the methods described in the specific examples. Optionally, the memory 1301 may be a physically independent unit, or as shown in FIG. 13, the memory 1301 and the processor 1302 are integrated together. In an example, the processor 1302 may include one or more processors, for example, a CPU 0 and a CPU 1 in FIG. 13. Optionally, when the encoding or decoding method in the foregoing embodiment is partially or entirely implemented by software, the communication apparatus 1300 may alternatively include only the processor 1302. The memory 1301 configured to store the part or all of the program is located outside the polar code communication apparatus 1300. The processor 1302 is connected to the memory 1301 by a communication line (for example, a circuit/bus) 1340, and is configured to read and execute the program stored in the memory 1301. Further, the encoded data output by the communication apparatus 1300 is modulated by a modulator 1310 and then output to a transceiver 1320. The transceiver 1320 performs corresponding processing (including, but not limited to, digital-to-analog conversion and/or frequency conversion processing) on the modulated sequence, and then send the sequence through an antenna 1330. Correspondingly, during decoding, a signal of an air interface is received through the antenna 1230, and then, transmitted through the transceiver 1220 to a demodulator 1210 for processing. The signal that has been processed by the demodulator 1210 is transmitted to the logic circuit 1202 through the communication interface 1201 for decoding. It is easy to understand that, from a perspective of product integration, when some conditions permit, the modulator 1310 and the transceiver 1320 may be a function implementation module or a physical implementation unit, or the transceiver 1320 and the antenna 1330 may be a function implementation module or a physical implementation unit. Similarly, one physical entity may be used to implement functions of the modulator and the demodulator. For example, 1310 shown in the figure may also be a demodulator, and the processor 1302 may also have a decoding function. Specifically, during specific implementation, the communication apparatus 1300 may be a chip or an integrated circuit.

In an optional implementation, the communication apparatus 1300 further includes an output device 1303 and an input device 1304. For example, the input device 1304 is a device such as a (virtual) keyboard, a microphone, or a joystick, and the output device 1303 is a device such as a display screen or a speaker (speaker). A person skilled in the art may figure out that the communication apparatus 1300 may be a mobile phone, a base station, an automobile, an industrial robot, a satellite, a network server, a desktop computer, a portable computer, a tablet computer, a wireless terminal, an embedded device, a chip system, or a device having a similar structure or circuit in FIG. 13. In addition, the composition structure shown in FIG. 13 does not constitute a limitation on the communication apparatus. In addition to the components shown in FIG. 13, the communication apparatus may include more or fewer components than those shown in the figure, or combine some components, or have different component arrangements.

The processor may be a central processing unit (central processing unit, CPU), a network processor (network processor, NP), or a combination of a CPU and an NP. The processor may further include a hardware chip. The hardware chip or the logic circuit may be an application-specific integrated circuit (application-specific integrated circuit, ASIC), a programmable logic device (programmable logic device, PLD), or a combination thereof. The PLD may be a complex programmable logic device (complex programmable logic device, CPLD), a field-programmable gate array (field-programmable gate array, FPGA), a generic logic array (generic logic array, GAL), or any combination thereof. The memory in the foregoing embodiments may include a volatile memory (volatile memory), for example, a random-access memory (random-access memory, RAM). Alternatively, the memory may include a non-volatile memory (non-volatile memory), such as a flash memory (flash memory), a hard disk drive (hard disk drive, HDD), or a solid-state drive (solid-state drive, SSD). Alternatively, the memory may include a combination of the foregoing types of memories.

The transceiver may transmit and receive signaling over any type of communication medium. In some embodiments, the transceiver transmits and receives signaling over a wireless medium. For example, the transceiver may be a wireless transceiver configured to perform communication based on the following wireless telecommunications protocol: a cellular protocol (for example, Long Term Evolution (Long Term Evolution, LTE)), a wireless local area network (wireless local area network, WLAN) protocol (for example, Wi-Fi), or any other type of wireless protocol (for example, Bluetooth or near-field communication (near-field communication, NFC)). The type of the antenna may include a single antenna, a plurality of separate antennas, or a multi-antenna array for multi-layer communication such as a single-input multiple-output (single-input multiple-output, SIMO), multiple-input single-output (multiple-input-single-output, MISO), or multiple-input multiple-output (multiple-input multiple-output, MIMO). In other embodiments, the transceiver transmits and receives signaling over a wired medium such as twisted pair cables, coaxial cables, or optical fibers. Specific processing systems and/or transceivers may be all of the components shown or a subset of the components, and the degrees of integration of the devices may be different from each other.

A person skilled in the art should understand that a method, a system, or a computer program product may be provided based on embodiments of this application. Therefore, the foregoing embodiments may be implemented in an implementation form that is completely hardware, completely software, or a combination of software and hardware aspects. In addition, in this application, a form of a computer program product that is implemented on one or more computer-usable storage media (including, but not limited to, a disk memory, a CD-ROM, an optical memory, and the like) that include computer-usable program code may be used. Specifically, this application provides a computer storage medium, storing a computer program. The computer program is configured to perform the foregoing polar code encoding method, or may be further configured to perform the methods including, but not limited to, the methods described in the specific examples, or perform the foregoing polar code decoding method. In addition, this application further provides a computer program product including instructions. When the computer program product is partially or entirely run on a computer, the foregoing polar code encoding method is performed, or the methods including, but not limited to, the methods described in the specific examples may be performed, or the foregoing polar code decoding method is performed.

This application is described with reference to the flowcharts and/or block diagrams of the method, the device (system), and the computer program product according to embodiments of this application. It should be understood that computer program instructions may be for implementing each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flowcharts and/or in one or more blocks in the block diagrams.

The computer program instructions may alternatively be stored in a computer-readable memory that can indicate a computer or another programmable data processing device to work in a specific manner, so that the instructions stored in the computer-readable memory generate an artifact that includes an instruction apparatus. The instruction apparatus implements a specific function in one or more procedures in the flowcharts and/or in one or more blocks in the block diagrams.

The computer program instructions may alternatively be loaded onto a computer or another programmable data processing device, so that a series of operations and steps are performed on the computer or the another programmable device, to generate computer-implemented processing. Therefore, the instructions executed on the computer or the another programmable device provide steps for implementing a specific function in one or more procedures in the flowcharts and/or in one or more blocks in the block diagrams.

1. A polar code decoding method, comprising:
receiving an encoded sequence, wherein the encoded sequence is obtained by performing polar encoding on a first bit sequence, a first sub-channel set corresponding to the first bit sequence comprises at least K sub-channels determined based on reliability of the first sub-channel set, the K sub-channels carry information bits, the first sub-channel set comprises S sub-channel subsets, an i^{th} sub-channel subset in the S sub-channel subsets comprises Ji sub-channels carrying auxiliary bits and Ki sub-channels in the K sub-channels, wherein the Ki sub-channels carry information bits, sequence numbers of the Ji sub-channels carrying the auxiliary bits are after sequence numbers of the Ki sub-channels, the auxiliary bits comprise a known redundancy check bit, and K, S, Ji, and Ki are integers; and
performing polar decoding based on the encoded sequence, to obtain the information bits.

2. The polar code decoding method according to claim 1, wherein the first sub-channel set is a channel set from which a shorten sub-channel is excluded.

3. The polar code decoding method according to claim 2, wherein the at least K sub-channels comprise (K+J) sub-channels, wherein the J sub-channels carry auxiliary bits.

4. The polar code decoding method according to claim 1, wherein the i^{th} sub-channel subset comprises (Ki+Ji) sub-channels, the (Ki+Ji) sub-channels are determined based on reliability of the i^{th} sub-channel subset, and the (Ki+Ji) sub-channels carry information bits and the auxiliary bits.

5. The polar code decoding method according to claim 4, wherein reliability of the (Ki+Ji) sub-channels is higher than reliability of a remaining sub-channel in the i^{th} sub-channel subset.

6. The polar code decoding method according to claim 1, wherein the at least K sub-channels determined based on the reliability of the first sub-channel set comprise the K sub-channels determined based on the reliability of the first sub-channel set.

7. The polar code decoding method according to claim 6, wherein sequence numbers of the Ji sub-channels are greater than a sequence number of a remaining sub-channel in the i^{th} sub-channel subset.

8. The polar code decoding method according to claim 7, wherein the Ki sub-channels are determined based on reliability of a third sub-channel set, wherein the third sub-channel set is the i^{th} sub-channel subset from which the Ji sub-channels are excluded, and the Ki sub-channels carry the information bits.

9. The polar code decoding method according to claim 1, wherein a total quantity J of the auxiliary bits is determined based on a quantity T of times of checking a check result of the auxiliary bits during polar decoding, and T is a positive integer.

10. An apparatus, comprising:
at least one processor; and
a memory having instructions stored thereon that, when executed by the at least one processor, cause the apparatus to:
receive an encoded sequence, wherein the encoded sequence is obtained by performing polar encoding on a first bit sequence, a first sub-channel set corresponding to the first bit sequence comprises at least K sub-channels determined based on reliability of the first sub-channel set, the K sub-channels carry information bits, the first sub-channel set comprises S sub-channel subsets, an i^{th} sub-channel subset in the S sub-channel subsets comprises Ji sub-channels carrying auxiliary bits and Ki sub-channels in the K sub-channels, wherein the Ki sub-channels carry information bits, sequence numbers of the Ji sub-channels carrying the auxiliary bits are after sequence numbers of the Ki sub-channels, the auxiliary bits comprise a known redundancy check bit, and K, S, Ji, and Ki are integers; and
perform polar decoding based on the encoded sequence, to obtain the information bits.

11. The apparatus according to claim 10, wherein the first sub-channel set is a channel set from which a shorten sub-channel is excluded.

12. The apparatus according to claim 11, wherein the at least K sub-channels comprise (K+J) sub-channels, wherein the J sub-channels carry auxiliary bits.

13. The apparatus according to claim 10, wherein the i^{th} sub-channel subset comprises (Ki+Ji) sub-channels, the (Ki+Ji) sub-channels are determined based on reliability of the i^{th} sub-channel subset, and the (Ki+Ji) sub-channels carry information bits and the auxiliary bits.

14. The apparatus according to claim 10, wherein the at least K sub-channels determined based on the reliability of the first sub-channel set comprise the K sub-channels determined based on the reliability of the first sub-channel set.

15. The apparatus according to claim 10, wherein a total quantity J of the auxiliary bits is determined based on a quantity T of times of checking a check result of the auxiliary bits during polar decoding, and T is a positive integer.

16. A non-transitory computer-readable storage medium having instructions stored thereon that, when executed by at least one processor, cause an apparatus to:
receive an encoded sequence, wherein the encoded sequence is obtained by performing polar encoding on a first bit sequence, a first sub-channel set corresponding to the first bit sequence comprises at least K sub-channels determined based on reliability of the first sub-channel set, the K sub-channels carry information bits, the first sub-channel set comprises S sub-channel subsets, an i^{th} sub-channel subset in the S sub-channel subsets comprises Ji sub-channels carrying auxiliary bits and Ki sub-channels in the K sub-channels, wherein the Ki sub-channels carry information bits, sequence numbers of the Ji sub-channels carrying the auxiliary bits are after sequence numbers of the Ki sub-channels, the auxiliary bits comprise a known redundancy check bit, and K, S, Ji, and Ki are integers; and
perform polar decoding based on the encoded sequence, to obtain the information bits.

17. The non-transitory computer-readable storage medium according to claim 16, wherein the first sub-channel set is a channel set from which a shorten sub-channel is excluded.

18. The non-transitory computer-readable storage medium according to claim 16, wherein the i^{th} sub-channel subset comprises (Ki+Ji) sub-channels, the (Ki+Ji) sub-channels are determined based on reliability of the i^{th} sub-channel subset, and the (Ki+Ji) sub-channels carry information bits and the auxiliary bits.

19. The non-transitory computer-readable storage medium according to claim 16, wherein the at least K sub-channels determined based on the reliability of the first sub-channel set comprise the K sub-channels determined based on the reliability of the first sub-channel set.

20. The non-transitory computer-readable storage medium according to claim 16, wherein a total quantity J of the auxiliary bits is determined based on a quantity T of times of checking a check result of the auxiliary bits during polar decoding, and T is a positive integer.
